(19) United States
(12) Patent Application Publication
(10) Pub. No.: US 2006/0119404 A1
(43) Pub. Date: Jun. 8, 2006

(54) Phase locked loop circuit

(75) Inventor: Tse-Hsien Yeh, Hsinchu City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/294,383

(22) Filed: Dec. 6, 2005

(30) Foreign Application Priority Data
Dec. 7, 2004 (TW) 93137821

(51) Int. Cl. H03L 7/06

(52) U.S. Cl. 327/157

(57) ABSTRACT

A circuit of the present invention applied for the PLL is disclosed. The circuit comprises a loop filter, a first charge pump, and a second charge pump. The loop filter includes a unit gain buffer, a first capacitor connected to the input terminal of the unit gain buffer and a ground, a second capacitor connected to the output terminal of the unit gain buffer and the ground, and a low pass filter consisting of a resistor and a third capacitor connected to the output terminal of the unit gain buffer. The first charge pump is coupled to the output terminal of the RC low pass filter, and the second charge pump coupled to the input terminal of the unit gain buffer in the loop filter. The second capacitor in loop filter circuit of the present invention and the improvement on the charge pump are improved the stability of the PPL and reduced the influence of the loop filter circuit by the unit gain buffer.

### FIELD OF THE INVENTION

The present invention relates to a phase locked loop circuit, more particularly to a charge pump circuit and a loop filter for using in the phase locked loop circuit.

### BACKGROUND OF THE INVENTION

A phase locked loop (PLL) circuit is generally used to control the stability of an operating frequency. FIG. 1 is a block diagram representing a conventional phase locked loop circuit 10 and includes a phase detector 12, a charge pump circuit 14, a loop filter 16 and a voltage controlled oscillator 18.

The phase detector 12 is used for detecting a phase difference between two input signals IN1, IN2, and outputs an up (UP) signal or a down (DN) signal to the charge pump circuit 14 upon detection of the phase difference. According to the received UP or DN signal, the charge pump circuit 14 outputs a controlling current to the loop filter 16 or vice versa. The controlling current is used for charging or discharging a capacitor of the loop filter 16, a detailed explanation of which will be given later in the following paragraphs. Finally, the loop filter 16 outputs a controlling voltage Vc to the voltage controlled oscillator 18, which, in turn, generates the signal IN2 based on the controlling voltage Vc

FIG. 2A illustrates a state when the phase detector 12 of the conventional PLL circuit 10 generates the UP signal. The phase detector 12 outputs the UP or DN signal after detection of the phase difference between the input signals IN1 and IN2. In FIG. 2A, the signal IN1 leads ahead of the signal IN2 by the phase difference θ1. The phase detector 12 is capable of detecting the phase difference θ1 and generating the UP signal. The pulse width of the UP signal is directly proportional to the phase difference θ1 of the signals IN1 and IN2. The UP signal is finally used to enhance the frequency of the signal IN2 so that the signals IN1 and IN2 stay in-phase (i.e there is no phase difference between the signals IN1 and IN2).

FIG. 2B illustrates a state when the phase detector 12 of the conventional PLL circuit 10 generates the DN signal. In FIG. 2B, the signal IN1 lags behind the signal IN2 by the phase difference θ2. The phase detector 12 is capable of detecting the phase difference θ2 and generating the DN signal. The pulse width of the DN signal is directly proportional to the phase difference θ2 of the signals IN1 and IN2. The DN signal is finally used to reduce the frequency of the signal IN2 so that the signals IN1 and IN2 stay in-phase (i.e. there is no phase difference between the signals IN1 and IN2).

FIG. 3 illustrates a block diagram of a first conventional technique to include a charge pump 20 and a loop filter 22. The charge pump 20 includes a first input current source 24, an up switch 25 (PMOS serves as the UP switch, called swUP25) coupled to the loop filter 22 via a connecting node A, and a down switch 27 (NMOS negative-channel metal oxide semiconductor serves as the DN switch, called swDN27) coupled to a first output current source 26. The loop filter 22 includes a resistor R cascading a capacitor C1 and a capacitor C2 in parallel manner. The swUP25 is controlled by the UP signal.

In receipt of the UP signal from the phase detector 12, the swUP25 is switched on to permit charging of the capacitor C1 since the former is in electrical communication with the latter. The swUP25 is switched off at the remaining period of the operating time. When the capacitor C1 is under the charging state, the loop filter 22 outputs a control voltage V_{c}=I₁×(R+1/SC1)(S=2f) to the voltage controlled oscillator 18 (capacitance C2 can be omitted in the calculation). When receiving the pulse of the descending signal DN, the swDN27 is switched on to permit the capacitor C1 discharging.

FIG. 4 illustrates a block diagram of a second conventional technique to include a charge pump 30 (replacing the charge pump 20) and a loop filter 22. The charge pump 30 includes a first input current source 40 coupled to the swUP44 and the swDN45 via the connecting node A. The first input current source 40 is coupled to the output current source 43, the resistor R, the capacitors C1′, and C2. A second input current source 42 is coupled to the swUP46 and the resistor R and the capacitor C1′ via a connecting nodes B and E, and is further coupled to the swDN47 and a second output current source 43 in series.

As disclosed in the first conventional technique, each of the swUP44 and the swUP46 is controlled by an UP signal. When the charge pump 30 and the loop filter 22 receive the UP signal, the swUP44 and the swUP46 both are switched on to permit an electrical current I₁ to flow into the resistor R via the connecting node A, and an electrical current I₂=(n−1/n)×I₁ to flow from the connecting node E into the node B, thereby disposing the charge pump 30 and the loop filter 22 under the charging state. The capacitor C1′ is being charged while the loop filter 22 outputs a controlled voltage Vc=I₁×R+(I₁−I₂)×1/SC1′=I₁×R+I₁/nSC1′=I₁×(R+1/SC1).

From the above equation, it can be observed that C1′=C1/n so that the capacitance of capacitor C1 of FIG. 3 can be reduced effectively. However, the swUP44 and the swUP46 of the system should be switched on or off simultaneously in order to maintain the validity of equation. The UP switches swUP44, swUP46 are disposed in the open-circuit condition at the remaining period of the operating time.

In case of receiving a DN signal, the DN switches swDN45, swDN47 are disposed in a closed-circuit condition, thereby disposing the charge pump 30 and the loop filter 22 in the discharge mode. At this time, the capacitor C_{1′} is disposed in a state to discharge therefrom.

FIG. 5 illustrates a block diagram of a third conventional technique to include the charge pump 30 and a loop filter 32 (replacing the loop filter 22 of FIGS. 3 and 4). The loop filter 32 includes a resistor R, a unit gain buffer 48 and two capacitors C1 and C2. The unit gain buffer 48 has an output end coupled to the resistor R at the connecting node F and an input end coupled to the capacitor C1′ at the connecting node E in order to supply the voltage from the connecting node E to the connecting node F. The gain of the unit gain buffer is 1 or nearly 1, and the unit gain buffer can be made by a source follower or a voltage follower which is a non-inverting operational amplifier with unity gain.

Upon receiving an UP signal, the swUP44 and the swUP46 of the charge pump 30 are switched on to permit the current I₁ to flow to charge the capacitor C2 from the node A and the current I₂=I₁/n charge the capacitor C1′ from the nodes B. The unit gain buffer 48 will not permit the current from the second input current source 42 to flow into F via the node E. The loop filter 32 will output a controll voltage Vc=I₁R+I₂/SC1′=I₁×(R+1/nSC1′)=I₁×(R+1/SC1).

From the above equation, it is found that C1′=C1/n so that the capacitance of the capacitor C1 can be reduced significantly. Meanwhile, the problem of simultaneously changing the switching modes of the switches in the charge pump circuit within the second conventional technique can be overcome. Thus, the second input and output current sources do not require the charge pump circuit under the swift switching mode of the switches. The UP switches swUP44, swUP46 are disposed in the open-circuit condition at the remaining period of the operating time.

The DN switches swDN45, swDN47 are disposed in the closed-circuit state when the charge pump circuit 30 and the loop filter 32 receive the DN signal, thereby disposing the latter two in the discharge mode. At this time, the capacitor C1′ is disposed in a state to discharge therefrom.

Of course, under certain conditions, the unit gain buffer 48 may cause some effects on the loop filter due to the internal resistance thereof. In case, the resistor R is several thousands of ohms, the internal resistance of the unit gain buffer 48 can be neglected. However, if the resistor R having a small resistance, for example, only several hundreds or less a hundred, the internal resistance Rₒ of the unit gain buffer 48 cannot be neglected. Thus, the controlled voltage outputted by the loop filter will be V_{c=}I₁×(R+Rₒ)+I₂/SC1′=I₁×(R+1/gm)+I₂/SC1′, where gm is conductance, gm=1/Rₒ. The internal resistance of the unit gain buffer 48 indeed affects the controlled voltage V_{c}.

A simple example is given below:

Assuming that the current inputted by the second input current source to the node E via the node B is zero, I₂=0, R=600Ω, conductance gm=4 m(1±40%)(A/V) where m=10⁻³ (gm may deviated from a predetermined value to about ±40% deviation due to semiconductor fabricating drift), then the loop filter may output the controlled voltage V_{c}=I₁×(R+1/gm). When the conductance gm=4 m, the loop filter may output the controlled voltage V_{c}=I₁×850. When the deviation reaches −40%, the conductance gm=4 m(1−40%)=2.4 m, then the loop filter will output the control voltage ΔV_{c}=I₁×1017=I₁×850×(1+20%). When the deviation attains 40%, the conductance gm=4 m(1+40%)=5.4 m, then the loop filter will output the control voltage ΔV_{c}=I₁×778=I₁×850×(1−22%). Under the most ideal condition, we do not appreciate that the internal resistance of the unit gain buffer 48 may affect the gain of the loop filter circuit. From the above example, it is perceived that when the circuit system requires a smaller resistor R and in case the resistance of the resistor R is substantially close to the internal resistance of the unit gain buffer 48, the internal resistance of the unit gain buffer 48 affects tremendously the output voltage of the loop filter (the control voltage is deviated as high as ±20%).

Some disadvantages provided by the charge pump and the loop filter of the conventional PLL system are as followings:

a. there are three problems in the conventional charge pump circuit.

1. Under the swift operation, the phase detector generally uses low-voltage elements (a general operating voltage is 1.5V), the driving signal outputted by the phase detector has a high voltage level equal to the potential of low voltage current source (a high voltage level of the outputted driving signal by the phase detector is 1.5V). But in order to enhance the controlled voltage range of the voltage controlled oscillator, the charge pump and the loop filter generally use high voltage elements (a general operating voltage is 3.3V). The input driving signal must attain a high voltage level equal to the potential of high current source (The high voltage level of the outputted driving signal by the phase detector is 3.3V). Therefore, the driving signal makes a transition supported by a low to high voltage converter, thereby causing the delay of the signal transmission. Moreover, the pulse width of the signal is also affected due to the fabrication drift;

2. The PMOS and NMOS are respectively used as the up and down switches, the switches unbalance easily under the swift switching since there is different switching rate between the PMOS and the NMOS transistors;

3. A charge sharing effect is occurred between the connecting nodes of the input current source and the up switch, and the connecting nodes of the output current source and the down switch; and

b: In the third conventional technique, the gain of the loop filter is determined by the fabrication drift. In some of the fabrication processes, in case we select a low resistance of a resistor (hundreds or less than hundred ohms), the internal resistance of the unit gain buffer 48 of the loop filter circuit can greatly affect the gain of the loop.

### SUMMARY OF THE PRESENT INVENTION

It is therefore a primary objective of the present invention that is providing a circuit for an application in a phase locked loop circuit (PLL) to reduce the influence by an unit gain buffer in the circuit.

It is therefore a primary objective of the present invention that is providing a circuit for an application in the PLL to reduce the driving voltage of switches, to improve the switching speed of switches, and to reduce the charge sharing phenomenon in the circuit.

According to the present invention, a charge pump and a loop filter circuit applied for the PLL comprises a loop filter, a first charge pump, and a second charge pump. The loop filter includes a unit gain buffer, a first capacitor connected to the input terminal of the unit gain buffer and a ground, a second capacitor connected to the output terminal of the unit gain buffer and the ground, and a low pass filter consisting of a resistor and a third capacitor connected to the output terminal of the unit gain buffer. The first charge pump, coupled to the output terminal of the RC low pass filter, includes a first current source, a first current sink consisting a first constant current sink and a first down switch wherein the first down switch is controlled by a down signal, and a second current sink consisting a second constant current sink and a first up switch wherein the first up switch is controlled by an inverse phase of up signal. When the first charge pump receives the UP signal, the up and the down are switched off, and the first current I₁=I₀ flows from the first charge pump into the output terminal of the low pass filter of the loop filter. When the first charge pump receives the DN signal, the up and the down are switched on, and the first current I₁=I₀ flows from the output terminal of the low pass filter in the loop filter to the first charge pump. The second charge pump, coupled to the input terminal of the unit gain buffer in the loop filter, includes a second current source consisting a constant current source and a second up switch wherein the second up switch is controlled by the inverse phase of up signal, and a third current sink consisting a third constant current sink and a second down switch wherein the second down switch is controlled by the down signal, wherein the second current source and the third current sink are connected in series. When the second charge pump receives the UP signal, the up switch is switched on and the down switch is switched off, and the second current I₂=I₀/n flows from the second charge pump into the input terminal of the unit gain buffer of the loop filter. When the second charge pump receives the DN signal, the up switch is switched off and the down switch is switched on, and the second current I₂=I₀/n flows from the input terminal of the unit gain buffer of the loop filter into the second charge pump.

The second capacitor in loop filter circuit according to the present invention is connected to the output terminal of the unit gain buffer and the ground. When the resistance of the resistor R is a small value, the second capacitor can be reduced the influence of the loop filter circuit by the unit gain buffer. In the first charge pump circuit, the first and the second current sinks are connected in parallel and first up and the first down switches are implemented by NMOS transistors to substitute for the switches implemented by the PMOS and the NMOS transistors. The driving signal controlled the first charge pump is supplied from the phase/frequency detector made by low voltage components or logic controller. It is a primary objective of the charge pump circuit to promote the swift switch rate, to enhance the speed and the stability of the transmission signal, and to reduce the charge sharing effect of the nodes.

### BRIEF DESCRIPTION OF THE DRAWINGS

The present exemplary preferred embodiment will be described in detail with reference to the accompanying drawings, in which:

FIG. 1 is a block diagram of a phase locked loop (PLL) according to the prior art;

FIG. 2A is a diagram illustrating operation of a phase detector of the PLL of the prior art when generating an up (UP) signal.

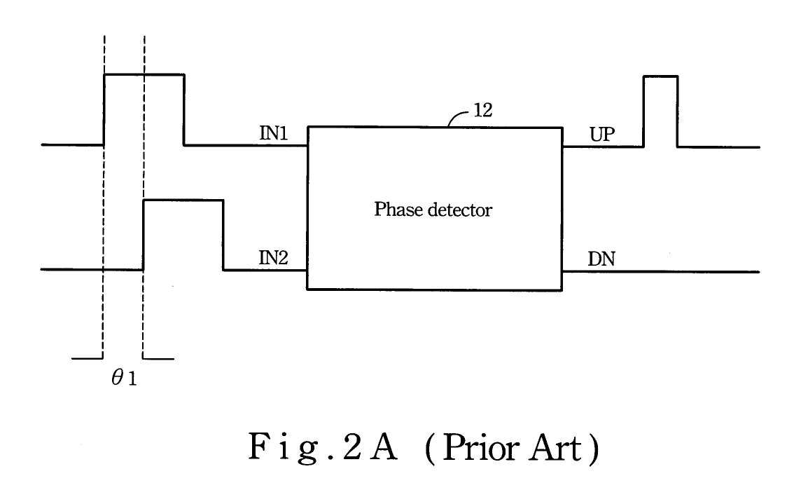

FIG. 2B is a diagram illustrating operation of the phase detector of the PLL of the prior art when generating a down (DN) signal.

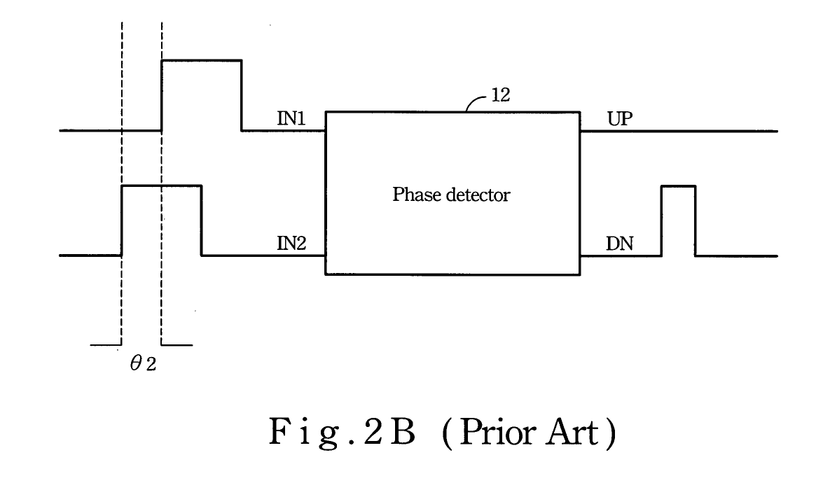

FIG. 3 is a circuit diagram of a charge pump circuit and a loop filter of the prior art.

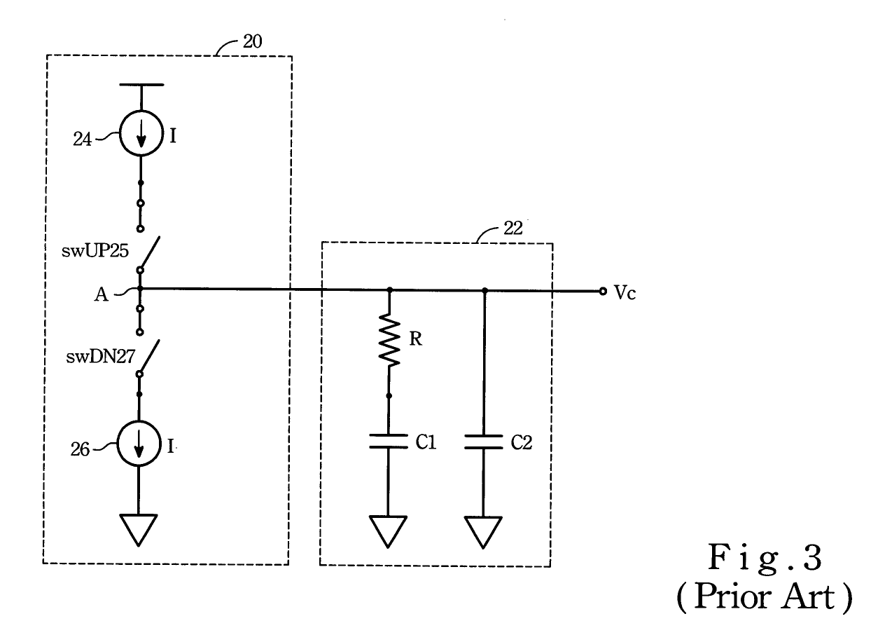

FIG. 4 is a circuit diagram of a charge pump circuit and a loop filter of the prior art.

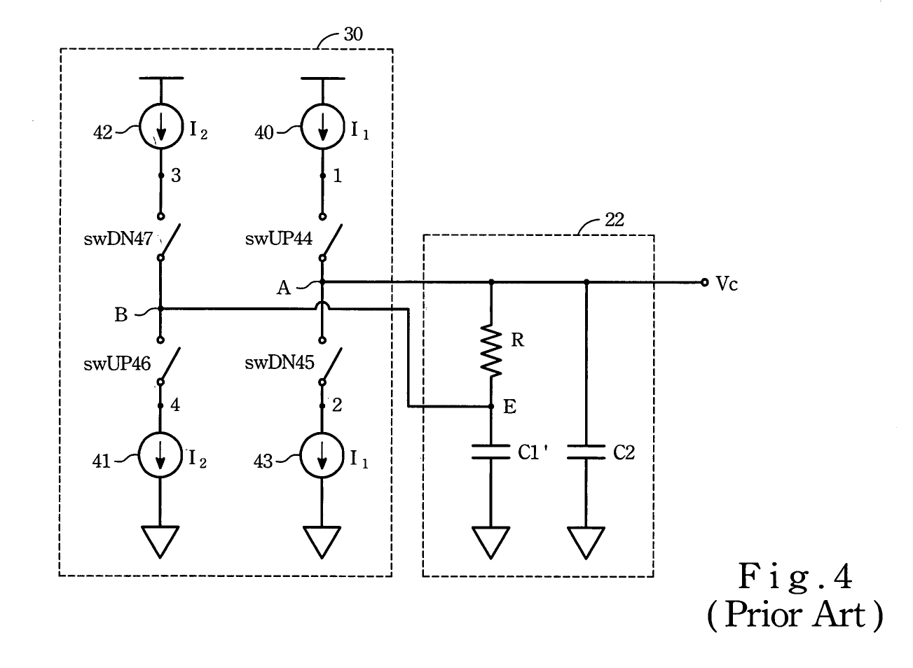

FIG. 5 is a circuit diagram of a charge pump circuit and a loop filter of the prior art.

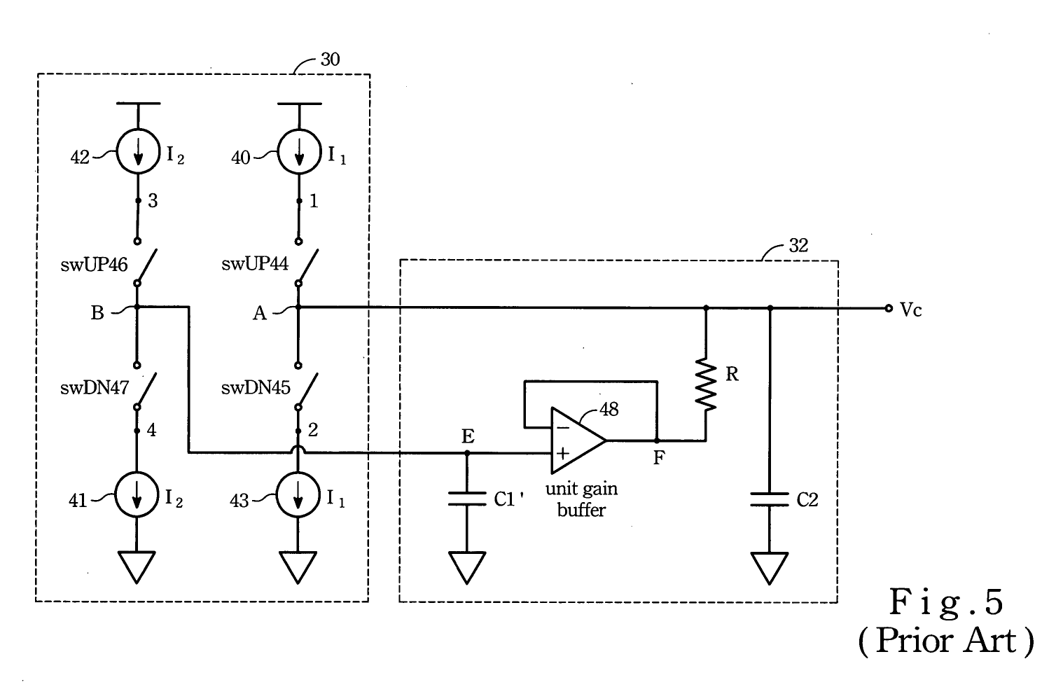

FIG. 6 is a circuit diagram of a charge pump circuit and a loop filter circuit according to an embodiment of the present invention.

### DETAILED DESCRIPTION OF THE PREFERRED EMBODIMENT

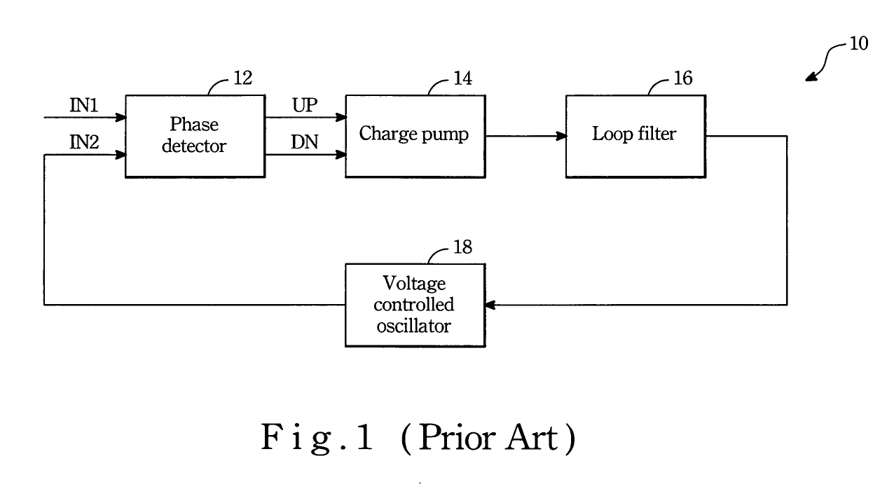

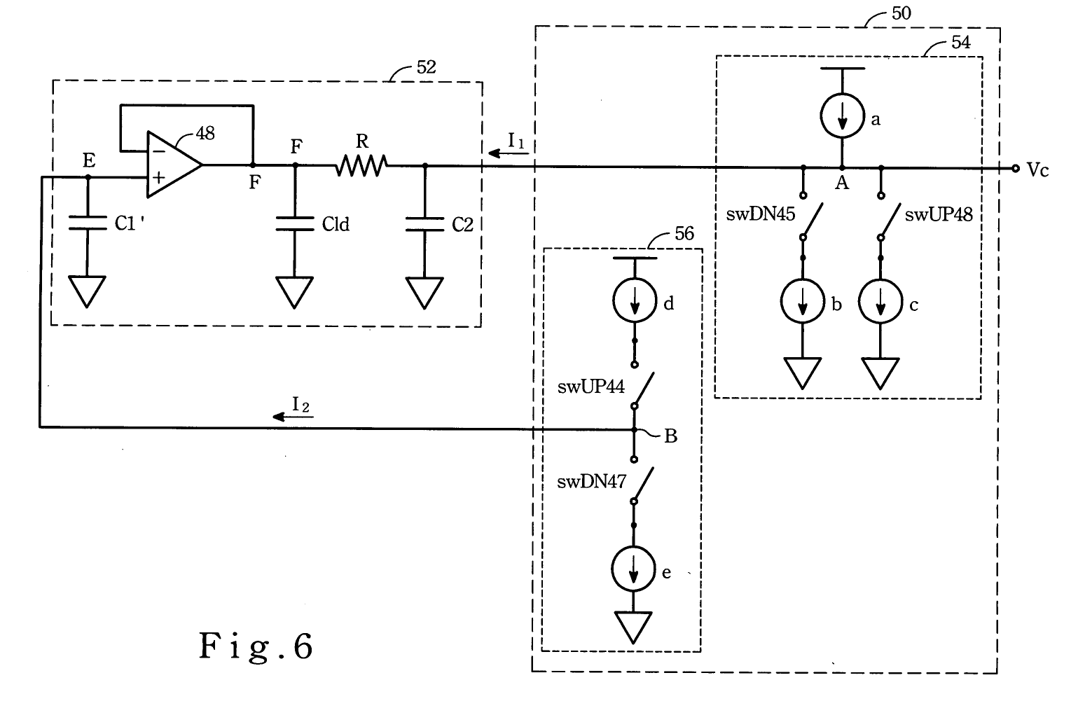

FIG. 6 is a circuit diagram of a charge pump and a loop filter according to one embodiment of the present invention. In FIG. 6, the charge pump 50 and the loop filter 52 are substituted for the charge pump circuit 14 and the loop filter 16 of the prior art. The phase detector 12 and the VCO 18 are preserved as they were shown in FIG. 1, and a detailed description thereof is omitted herein for brevity sake.

The loop filter 52 includes a unit gain buffer 48, a first capacitor C1′, a second capacitor C1d, and a low pass filter consisting of a resistor R and a third capacitor C2. As shown in FIG. 6, the low pass filter and second capacitor C1d are connected in parallel that one terminal connected to the output terminal of the unit gain buffer 48 and the other terminal to the ground. The first capacitor C1′ is connected between the input terminal of the unit gain buffer 48 and the ground. The unit gain buffer 48 supplies the voltage from the node E to the node F.

The charge pump circuit 50 includes a first charge pump 54 and a second charge pump 56. The first charge pump 54, coupled with the output terminal of the RC low pass filter, includes a constant current source (a), switches swDN45, swUP48, and constant current sinks (b), (c). The switches swDN45, swUP48 are implemented by two NMOS transistors switched by an inverse phase of up signal (UPB=UP_{BAR}) and a down (DN) signal, respectively. In FIG. 6, the constant current source (a) serves as a first current source, and the swDN45 and the constant current sink (b) are connected in series and then serve as a first current sink. On the other hand, the swUP48 and the constant current sink (c) are connected in series and then serve as a second current sink. The first current sink, the second sink and the first current source are then with one terminal thereof connected with the output terminal of the loop filter 52. The first charge pump 54 permits a first current I₁=I₀ to flow into the output terminal of the low pass filter in the loop filter.

When the first charge pump 54 receives the UP signal was high and the DN signal was low (it means UP=1, UPB=0, and DN=0), the swUP48 and the swDN45 are switched off, and the first current I₁=I₀ flows from the first charge pump 54 into the output terminal of the low pass filter of the loop filter. When the first charge pump 54 receives the UP signal was low and the DN signal was high (it means UP=0, UPB=1, and DN=1), the swUP48 and the swDN45 are switched on, and the first current I₁=I₀ flows from the output terminal of the low pass filter in the loop filter to the first charge pump 54.

The second charge pump 56 includes a constant current source (d), switches swUP44, swDN47 and another constant current sink (e). The constant current source (d) is connected in series with the switch swUP44 and then serves as the second current source. On the other hand, the switch swDN47 and the constant current sink (e) are connected in series and served as the third current sink. The switch swUP44 is implemented by a PMOS transistor and controlled by the UPB signal whereas the swDN47 is implemented by a NMOS transistor and controlled by the DN signal. The second current source and the third current sink are connected with their connection node coupled with the positive input terminal of the unit gain buffer 48 of the loop filter 52. The second charge pump 56 permits a second current I₂=I₀/n to flow into the input terminal of the unit gain buffer in the loop filter, where n≧1.

When the second charge pump 56 receives the high UP signal and the low DN signal (it means UP=1, UPB=0, and DN=0), the swUP44 is switched on and the swDN47 is switched off, and the second current I₂=I₀/n flows from the second charge pump 56 into the input terminal of the unit gain buffer of the loop filter. When the second charge pump 56 receives the low UP signal and the high DN signal (it means UP=0, UPB=1, and DN=1), the swUP44 is switched off and the swDN47 is switched on, and the second current I₂=I₀/n flows from the input terminal of the unit gain buffer of the loop filter into the second charge pump 56.

Upon receipt of an high UP signal and a low DN signal (it means UP=1, UPB=0, and DN=0), the swUP48 and swDN45 are switched off so as to permit the first current I₀ to flow from the first charge pump 54 into the third capacitor C2 and the resistor R via a node A, and the swUP44 is switched on so as to permit the second current I₂=I₀/n into the first capacitor C1′ via the node B and the node E. The charge pump 50 and the loop filter 52 are disposed in the charging state. The swUP48, the swDN45, and the swDN47 are switched on when the charge pump circuit 50 and the loop filter 52 receive the low UP signal and the high DN signal (it means UP=0, UPB=1, and DN=1). Thus, the first current I₁=I₀ flows from the loop filter 52 to the first current sink and the second current sink via node A, and the second current source I₂=I₀/n flows from the first capacitor C1′ into the constant current sink (e) via the node E and the node B. At this time, the first capacitor C1′ is disposed in a state to discharge.

Using two NMOS transistors as the up pulse switch and the down pulse switch has three benefits over the combination of a PMOS transistor and a NMOS transistor in the charge pump circuit. Firstly, by contrast to the former, the latter have a consistent switching rate no matter receiving up or down signal and NOMS transistor is known to have a faster switch rate than PMOS transistor. Thus, the charge pump circuit is expected to have characteristics of stable and faster switching rate according the present invention. Secondly, the driving signal for controlling the charge pump circuit is directly supplied by the control logic composed of low voltage components. A voltage shifter or a low to high converter is not demanded in the charge pump circuit. Thirdly, it can reduce the effect of the charge sharing due to the two NMOS transistors are operated by lower driving voltages. The problems that the up and the down switches implemented of PMOS transistor and NMOS transistor, respectively, depicted in the prior arts are overcome. In this embodiment, the second charge pump 56 is the same as prior art because the switching rate thereof is not as important as the first charge pump.

Therefore the circuit according to the present invention has advantages over the prior art PLL. A simple example is given below using the same data above.

Assuming that the second current I₂ inputted by the constant current source (d) to the node E via the node B is zero, I₂=0, R=600Ω, the resistance of the unit gain buffer Ro=1/gm, conductance gm=4 m(1±40%)(A/V) (gm may have ±40% drift due to fabrication varied, m=10⁻³), the second capacitance C1d=1.2 pF, the frequency fₒ=1.25 GHz, then the loop filter may output a control voltage Vc=I₁×(R+1/(gm+j2πfₒC1d)). When the conductance gm=4 m, the loop filter will output a control voltage Vc=I₁×(638−j90). The absolute value of the control voltage is |V_{c}|=644. As aforementioned, when the deviation reaches a negative limit 40%, the gm=4 m(1−40%)=2.4 m, then the loop filter 52 will output a control voltage ΔVc=I₁×(625−j99). The absolute value |ΔV_{c}|=633=644×(1−1.7%). When the deviation value reaches an positive limit 40%, the gm=4 m(1+40%)=5.4 m, then the loop filter 52 will output the control voltage ΔV_{c}=I₁×(647−j79). The absolute value of the controlled voltage is |ΔV_{c}|=651=644×(1+1.1%). From the above example, when the circuit system requires a smaller resistance R and the internal resistance of the unit gain buffer 48 has ±40% deviation due to fabrication drift, the present invention also can reduce of the loop gain variation due to the second capacitor C1d. It can lower the deviation down to ±2% from the ultimate limit ±20% according to the prior art.

In the embodiment, the switches of the first charge pump 54 are implemented by NMOS transistors, however, it is not intended to limit the claim scope, as is known by skilled in the art, PMOS transistors can replace for NMOS transistors. The combination of charge pump 50 and the loop filter 52 according to the present invention is an exemplary only. The other combination can be the loop filter 52 in accordance with the present invention and the charge pump 30 in accordance with the prior art to reduce the influence of the loop gain owe to the unit gain buffer 48, or another combination of charge pump circuit 50 with the loop filter 32 to improve the switching rate and stability of the switches effective which can attain the purpose of reducing the charge sharing effect.

The invention has been described in detail with reference to particular illustrative embodiments. It is understood that variations and modifications of the invention can be effected within the spirit and scope of the invention and as defined in the appended claims.

What is claimed is:

1. A circuit applied for a phase locked loop (PLL), said circuit receiving a phase control signal from a phase detector to control a voltage control oscillator (VOC), comprising:
a loop filter including a unit gain buffer, a resistor connected to an output terminal of said unit gain buffer in one end, a first capacitor connected in between an input terminal of said unit gain buffer and a ground, a second capacitor connected in between said output terminal of said unit gain buffer and said ground, and a third capacitor connected in between the other end of said resistor and said ground;
a first charge pump including a first current source, a first current sink having a first down-switch controlled by a down signal in series connected with a first constant current sink, and a second current sink having a first up-switch controlled by an inverse phase of an up signal in series connected with a second constant current sink wherein said first current sink and said second current sink are connected in parallel and having a connection node thereof coupled to an output terminal of said loop filter and said first current source; and
a second charge pump including a second current source having a second constant current source in series with a second up-switch controlled by said inverse phase of said up signal, and a third current sink having a second down-switch controlled by said down signal in series with a third constant current sink wherein said second current source and said third current sink having connection node thereof connected with said input terminal of said unit gain buffer,
whereby a first current Iₒ flowing from said first charge pump into said loop filter to charge said second capacitor, and a second current Iₒ/n flowing from said second charge pump into said loop filter to charge said first capacitor while said circuit receiving said inverse phase of said up signal, and said first current flowing out into said first charge pump by discharging said second capacitor and said second current Iₒ/n flowing out into said second charge pump by discharging said first capacitor while said circuit receiving said down signal, where n≧1.

2. The circuit of claim 1, wherein said first up switch, said first down switch, and said second down switch are NMOS transistors, and said second up switch is a PMOS transistor.

3. The circuit of claim 1, wherein said first up switch, said first down switch, and said second up switch are PMOS transistors, and said second down switch is an NMOS transistor.

4. The circuit of claim 1, wherein said first up switch, said first down switch, and said second down switch are turned off and said second up switch is turned on to permit said first current Iₒ flowing from said first current source into said loop filter and said second current Iₒ/n flowing from said second current source into said loop filter while said circuit receiving an inverse phase of an up signal.

5. The circuit of claim 1, wherein said first up switch, said first down switch, and said second down switch are turned on and said second up switch is turned off to permit said first current flowing from said loop filter into said first and second current sinks and said second current Iₒ/n flowing from said loop filter into said third current sink while said circuit receiving said down signal.

6. The circuit of claim 1, wherein said inverse phase of up signal and said down signal are outputted from said phase detector to said first and said second charge pumps.

7. The circuit of claim 1, wherein said second capacitor is used for reducing influence of the gain of said circuit caused by said unit gain buffer.

8. A charge pump circuit comprising:
a first current source;
a first current sink, including a down switch and a first constant current sink in series wherein said down switch is controlled by a down signal; and
a second current sink, including an up switch and a second constant current sink in series wherein said up switch is controlled by an inverse phase of up signal,
wherein said first current sink and said second current sink are connected in parallel and having a connection node thereof coupled to said first current source,
whereby a current Iₒ flowing out from said connection node of said first current source, said first current sink, and said second current sink while said charge pump receiving an inverse phase of an up signal, and said current Iₒ flowing from said first current source to said first current sink and second current sink while said charge pump receiving said down signal.

9. The charge pump circuit of claim 6, wherein said down switch and said up switch are NMOS transistors.

10. The charge pump circuit of claim 6, wherein said down switch and said up switch are PMOS transistors.

11. A loop filter circuit comprising:
a unit gain buffer;
a resistor connected to the output terminal of said unit gain buffer in one end;
a first capacitor connected between the input terminal of said unit gain buffer and a ground terminal;
a second capacitor connected between said output terminal of said unit gain buffer and said ground terminal; and
a third capacitor connected between the other end of said resistor and said ground terminal.
